(19) United States
(12) Patent Application Publication
(10) Pub. No.: US 2014/0140137 A1
(43) Pub. Date: May 22, 2014

(54) NAND-TYPE NON-VOLATILE SEMICONDUCTOR STORAGE DEVICE

(71) Applicant: Kabushiki Kaisha Toshiba, Minato-ku (JP)

(72) Inventor: Shigeo KONDO, Mie-ken (JP)

(73) Assignee: Kabushiki Kaisha Toshiba, Minato-ku (JP)

(21) Appl. No.: 14/017,670

(22) Filed: Sep. 4, 2013

(30) Foreign Application Priority Data
Nov. 20, 2012 (JP) 2012-254752

(51) Int. Cl. G11C 16/34

(52) U.S. Cl. CPC G11C 16/3404
USPC 365/185.17

(57) ABSTRACT

According to one embodiment, a NAND-type non-volatile semiconductor storage includes a memory cell array and a control circuit. The memory cell array has a memory string in which more than one of memory cells are connected in series, a word line connected to more than one of memory cells, and a bit line connected to one end of the memory string. The control circuit performs a program operation, a verify operation, and a step-up operation in a program operation loop. The control circuit performs the program operation to apply a program voltage to the word line. The control circuit performs the verify operation after the program operation. The control circuit performs the step-up operation to program a memory cell judged to be insufficiently programmed at the verify-read operation using a step-up voltage. The control circuit sets the step-up voltage increasing, each time the step-up operation is performed.

### CROSS-REFERENCE TO RELATED APPLICATION

This application is based upon and claims the benefit of priority from the prior Japanese Patent Application No. 2012-254752, filed on Nov. 20, 2012, the entire contents of which are incorporated herein by reference.

### FIELD

Embodiments described herein relate to a NAND-type non-volatile semiconductor storage device.

### BACKGROUND

In a NAND-type non-volatile semiconductor storage device, such as a NAND-type flash memory, data is stored in the form of a threshold voltage by controlling the amount of electric charge in floating (unconnected) conductive gates. The threshold voltage is adjusted to a certain value corresponding to the data to be stored. However, a large number of cells in a memory array have a finite-width distribution in threshold voltages even for the same data.

Recently, a physical interval between memory cells has been becoming narrower and narrower due to increase of storage capacity and cell number density. This shrinkage of cell size brings greater “cell-to-cell interference” (the threshold voltage is affected by the change of the state of neighboring cells). As a result, the width of the threshold voltage distribution of the memory cells is becoming broader. On the other hand, the whole possible threshold voltage window from the minimum to the maximum is limited or even becoming narrower as well. Thus, threshold voltage margin to keep one voltage range apart from another is being reduced, which results in increase of erroneous writing of data and degradation of the reliability.

### BRIEF DESCRIPTION OF THE DRAWINGS

FIG. 1 is one example of a configuration diagram showing a NAND-type non-volatile semiconductor storage device according to an embodiment;

FIG. 2 is one example of a circuit diagram showing a memory cell array according to the embodiment;

FIG. 3(a) and FIG. 3(b) are one example of sectional views showing a memory cell and a selection transistor, respectively, according to the embodiment;

FIG. 4 is a one example of sectional view showing a NAND-type flash memory according to the embodiment;

FIG. 5 is one example of a diagram showing voltages supplied to the respective regions shown in FIG. 4;

FIG. 6 is one example of a diagram showing threshold voltage distributions of the memory cells according to the embodiment;

FIG. 7 is one example of a flow chart showing a program operation loop of the NAND-type flash memory according to the embodiment;

FIG. 8 is one example of a timing chart showing a voltage applied to a selected word line in a program operation of the NAND-type flash memory according to the embodiment;

FIG. 9 is one example of a diagram showing the natural threshold voltage distribution of the memory cells according to the embodiment;

FIG. 10 is one example of a diagram showing evolution of the threshold voltage distribution of the memory cells in program operation loops according to the embodiment;

FIG. 11 is one example of a diagram showing the natural threshold voltage distribution of the memory cells in a comparative example according to the embodiment;

FIG. 12 is one example of a diagram showing evolution of the threshold voltage distribution of the memory cells in program operation loops in the comparative example according to the embodiment;

FIG. 13 is one example of a diagram showing a simulation result of a program operation according to the embodiment; and

FIG. 14 is one example of a diagram showing a simulation result of a program operation according to the embodiment.

### DETAILED DESCRIPTION

According to one embodiment, a NAND-type non-volatile semiconductor storage includes a memory cell array and a control circuit. The memory cell array has a memory string in which more than one of memory cells are connected in series, a word line connected to more than one of memory cells, and a bit line connected to one end of the memory string. The control circuit performs a program operation, a verify operation, and a step-up operation in a program operation loop. The control circuit performs the program operation to apply a program voltage to the word line. The control circuit performs the verify operation after the program operation. The control circuit performs the step-up operation to program a memory cell judged to be insufficiently programmed at the verify-read operation using a step-up voltage. The control circuit sets the step-up voltage increasing, each time the step-up operation is performed.

Hereinafter, more than one of further embodiments will be described with reference to the drawings. In the drawings, the same symbols indicate the same of similar portions.

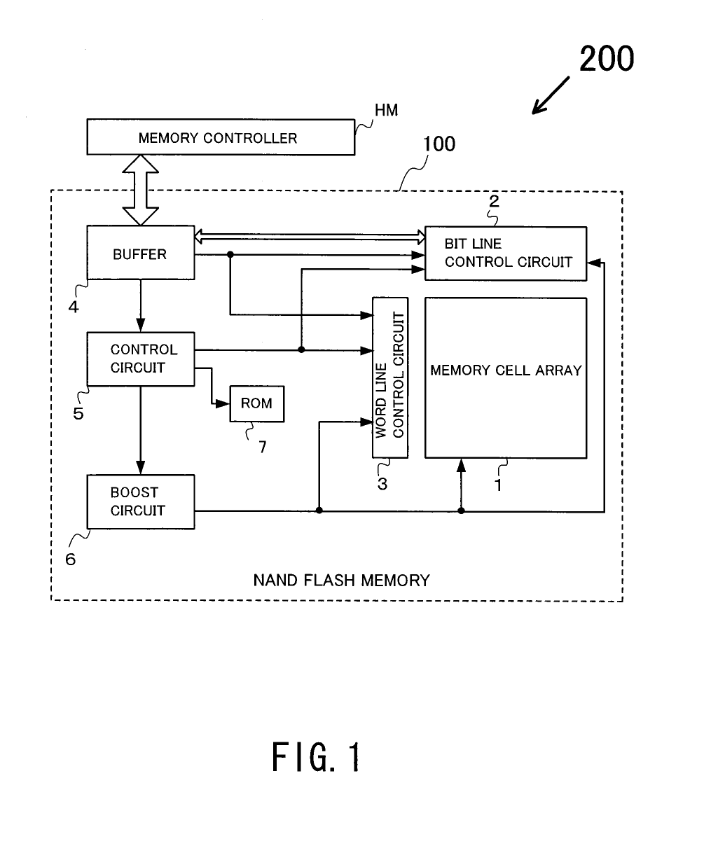

A NAND-type non-volatile semiconductor storage device according to the embodiment is described below with reference to the drawings. FIG. 1 is one example of a configuration diagram showing the NAND-type non-volatile semiconductor storage device.

In the embodiment, it is possible to extend the threshold voltage margin and improve reliability of NAND-type flash memories without loss of operation speed.

As shown in FIG. 1, a NAND-type non-volatile semiconductor storage device 200 includes a NAND-type flash memory 100 and a memory controller HM. The NAND-type flash memory 100 includes a memory cell array 1, a bit line control circuit 2, a word line control circuit 3, a buffer 4, a control circuit 5, a boost circuit 6, and a ROM 7. The memory cell array 1 arranges memory cells MC to store data in a matrix shape, for example.

The bit line control circuit 2 and the word line control circuit 3 are connected to the memory cell array 1. The bit line control circuit 2 controls a voltage of the bit line BL. The word line control circuit 3 controls a voltage of the word line WL.

The memory controller HM generates various commands CMD to control the operation of the NAND-type flash memory 100, an address ADD, and data DT, and outputs them to the buffer 4. Also these commands may be supplied from an external host or an outside device as well as the memory controller HM. Data stored in the buffer 4 is transformed to the bit lines BL selected by the bit line control circuit 2 through a data input/output line. The various commands CMD are input to the control circuit 5 through a command register (not shown), for example. The address ADD is input to the bit line control circuit 2 and the word line control circuit 3 through an address register. The booster circuit 6 is controlled based on the command CMD and the address ADD. The control circuit 5, the bit line control circuit 2, and the word line control circuit 3 perform various operations to the memory cell MC.

The boost circuit 6, under the control of the control circuit 5, generates voltages for programming, reading and erasing, and supplies these voltages to the bit line control circuit 2, the word line control circuit 3, etc. Then the bit line control circuit 2 and the word line control circuit 3 perform read, program, and erase operations to the memory cell MC.

The bit line control circuit 2 and the word line control circuit 3 are sometimes regarded as a part of “a control circuit”, and in such a case the term “control circuit” refers to whole the bit line control circuit 2, the word line control circuit 3, and the control circuit 5.

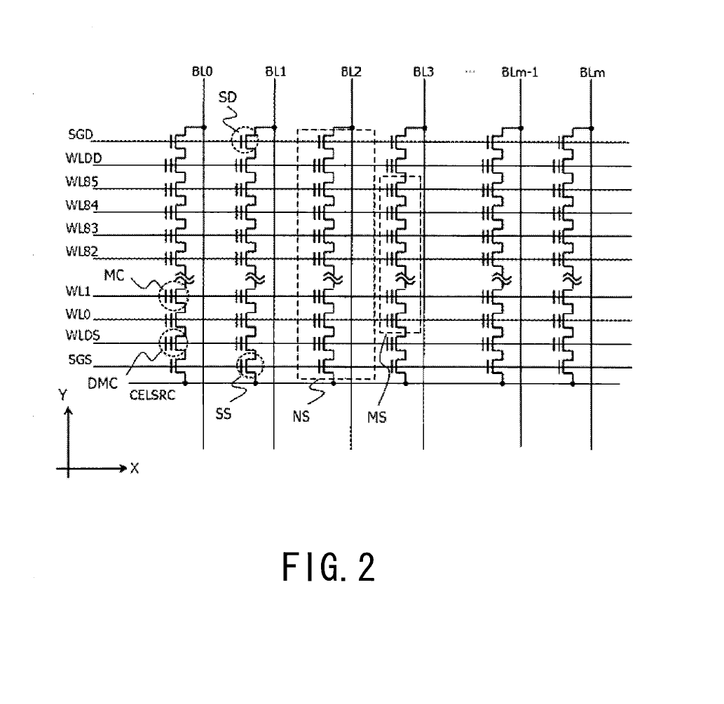

FIG. 2 is one example of a circuit diagram showing the memory cell array 1. As shown in FIG. 2, the memory cell array 1 includes bit lines BL, word lines WL, a common source line CELSRC, and the memory cells MC. The memory cell MC stores data of n bits (n is a natural number (n≧1)) in one memory cell. The memory cells MC are arranged in the memory cell array 1. The memory cells MC are arranged in the memory cell array 1. A “memory string” MS is defined as a set of memory cells MC on a single bit line between select transistors SS and SD. The memory string MS is composed of 86 memory cells MC, for example, which are connected in series in the bit line direction (the Y direction in FIG. 2). A “NAND string” NS is a set of the memory string MS and the two select transistors SS and SD. Dummy memory cells DMC may be disposed between the memory strings MS and the select transistors SD and/or between the memory strings MS and the select transistors SS.

More than one (m+1, in FIG. 2) NAND string NS is arranged in the word line direction (X direction in FIG. 2). The NAND string NS has one end connected to one of the bit lines BL and the other end connected to a common source line CELSRC. The select transistor SD is connected to a select gate SGD. The select transistor SS is connected to a select gate SGS.

The word line WL extends in the word line direction, and commonly connects the memory cells MC lining up in the word line direction. The memory cells MC connected in the word line direction composes one page. One page can be arbitrarily determined, such as 16 k bits, 8 k bits, for example. The NAND strings NS arranged in the word line direction compose a block. An erase operation is performed block by block.

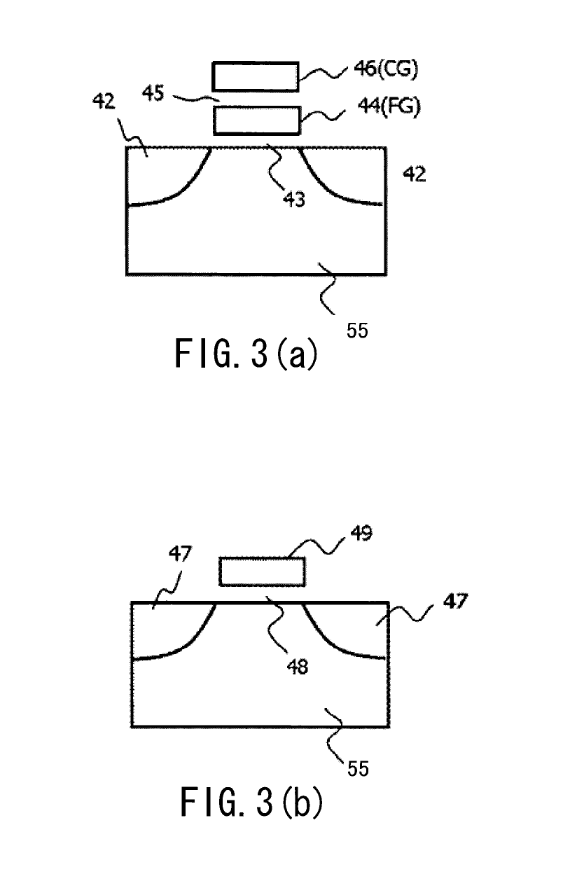

FIGS. 3(a) is one example of a sectional view showing the memory cell. FIG. 3(b) is a sectional view showing the selection transistor. As shown in FIG. 3(a), n-type diffusion layers 42 as a source and a drain of the memory cell are formed in a surface of a P-type cell well 55. A gate insulating film 43, a charge storage layer (FG) 44, an insulating film 45, and a control gate (CG) 46 are formed and stacked on the cell well 55. As shown in FIG. 3(b), n-type diffusion layers 47 as a source and a drain of the select gate are formed in a surface of the cell well 55. A gate conductor 49 is formed on the cell well 55 through a gate insulating film 48.

A threshold voltage of the memory cell can be changed by storing electric charge in the charge storage layer (or a floating gate; FG). Data can be stored by assigning data in accordance with the threshold voltage. Usually, a number of memory cells are used for storing large data, and their threshold voltages are distributed with finite width corresponding to the data.

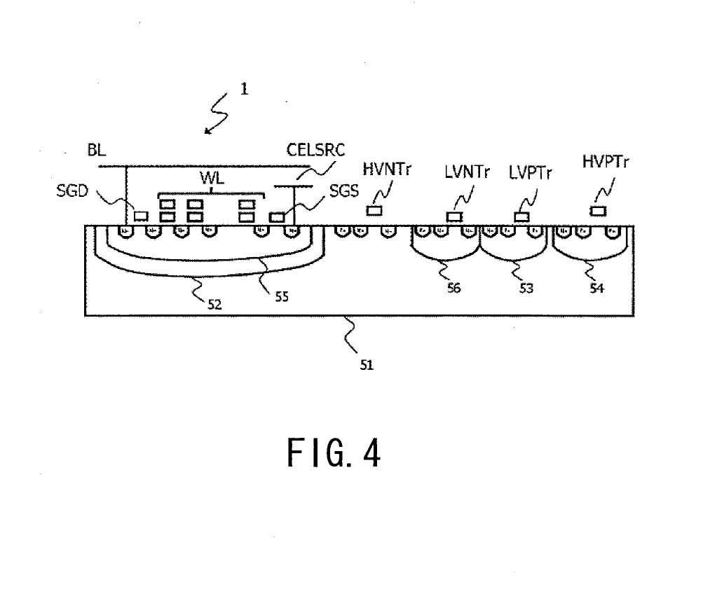

FIG. 4 is one example of a sectional view showing the NAND-type flash memory. As shown in FIG. 4, in the NAND-type flash memory 100, an N-type well region 52, an N-type well region 53, an N-type well region 54, and a P-type well region 56 are formed in a P-type semiconductor substrate 51. The cell well 55 is formed in the N-type well region 52. A memory cell transistor constituting the memory cell array 1 is formed on the surface region of the cell well 55. A low voltage P-channel transistor LVPTr is formed on the surface region of the N-type well region 53. A low voltage N-channel transistor LVNTr is formed on the surface region of the P-type well region 56. A high voltage N-channel transistor HVNTr for connecting the word line WL and the word line control circuit 3 is formed on the surface region of the substrate 51. A high voltage P-channel transistor HVPTr is formed on the N-type well region 54. The high voltage N-channel transistor HVNTr and the high voltage P-channel transistor HVPTr have thicker gate insulating films and higher breakdown voltages compared with the low voltage N-channel transistor LVNTr and the low voltage P-channel transistor LVPTr.

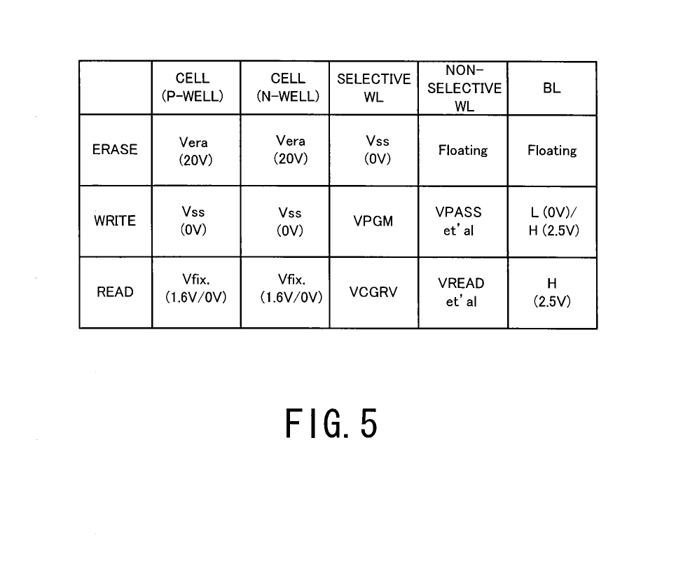

FIG. 5 shows one example of a voltage diagram supplied to the respective regions shown in FIG. 4 in erase, program, and read operations. “Vera” denotes an erase voltage supplied to the substrate during erasing. “Vss” denotes a ground voltage. “Vdd” denotes a power supply voltage. “VPGM” denotes a program voltage supplied to a selected word line during programming. “ VCGRV ” denotes a verify-read voltage supplied to a selected word line during the verify-read operation. “VREAD” denotes a read pass voltage supplied to a unselected word line during reading. “VPASS” denotes a write pass voltage supplied to a unselected word line during programming.

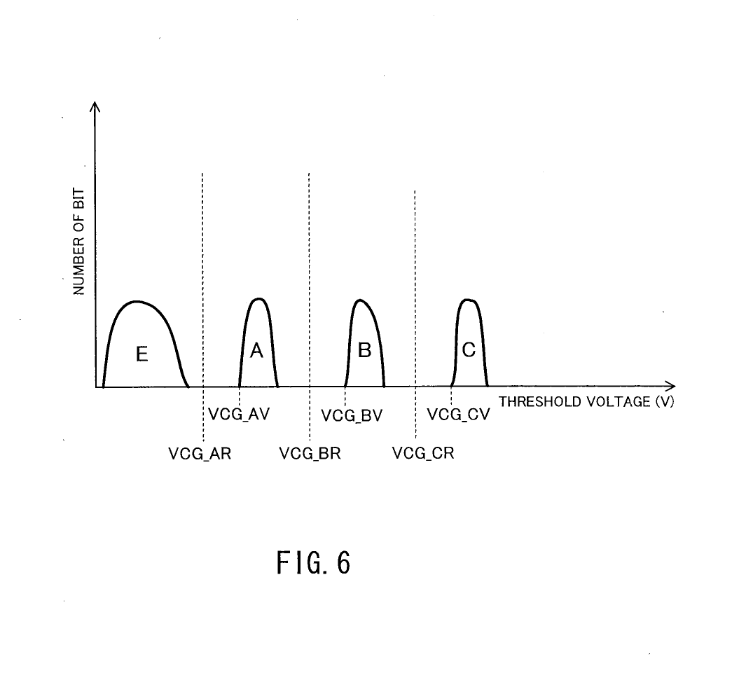

The relation between the threshold voltage distribution of the memory cells MC and data storage is described below with reference to FIG. 6. FIG. 6 schematically shows one example of threshold voltage distributions of whole memory cells on one word line or a NAND block. The vertical axis shows the number density of cells, and the transverse axis shows the threshold voltage in FIG. 6. When each memory cell MC has four possible programmed states (two bits per cell), for example, the threshold voltage space can be partitioned into four regions, and the threshold voltage distribution is divided into four fragments.

Here, the distribution fragments (or voltage regions) are defined as “E” (erased state), “A”, “B”, and “C” distributions (or states) in the growing order of the threshold voltage, respectively. Two bits data “1 1”, “1 0”, “0 0”, and “0 1” are assigned to the “E”, “A”, “B”, and “C” states, respectively, for example.

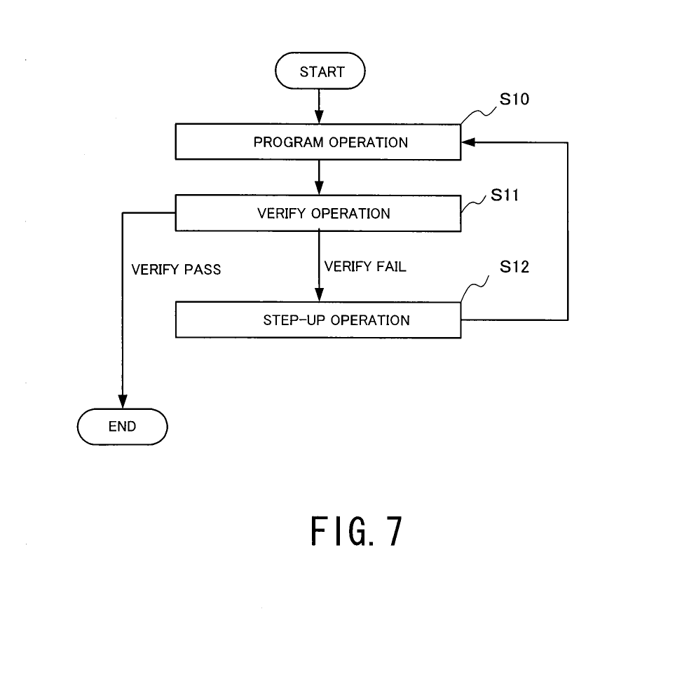

A program operation loop of the NAND-type flash memory 100 is described below with reference to a flow chart of a program operation loop (FIG. 7). At this point, one point of the present invention lies in how the program voltage is incrementally raised in the program operation loop.

As shown in FIG. 7, the program operation loop has a program operation (a step S10) to apply a program voltage, a verify-read operation (a step S11) to confirm threshold voltages of the memory cells after the program operation, and a step-up operation (a step S12) to calculate a new program voltage in an incremental step-up manner. In addition, the verify-read operation does not have to be performed every program operation loop. There can exist various modifications such as the verify-read operation is performed only once a few program operation loops.

At the beginning of the program operation loop, the boost circuit 6 and the control circuit 5 apply the program voltage VPGM to a selected word line and apply the program-pass voltage VPASS etc. to the unselected word lines (the “selected” word line is a word line to be programmed and “unselected” word lines are all the other word lines of the same block) (the step S10). VPASS values of all the unselected word lines can be uniformly equal or not. The order of the word line selection in a block is in the source-to-drain direction, that is, the word line closest to the source-side select transistor SGS is programmed first, and the word line closest to the drain-side select transistor SGD is programmed last, in general.

There are about 10⁴ to 10⁵ memory cells (MC) or memory cell strings (MS) on one word line (WL). During the program operation, all the memory cells connected to the selected word line are commonly applied to the program voltage VPGM. However, cells are selected if they are targeted to be programmed or not independently. Hereinafter, “selected” cells are referred to as the memory cells targeted to be programmed. Furthermore, “unselected” cells are referred to as the memory cell targeted not to be programmed. In the same way, “selected” bit lines are defined as bit lines that the selected cells are connected, and “unselected” bit lines are defined as bit lines that the selected cells are not connected. The bit line control circuit 2 imposes 0V, for example, on the selected bit lines. Then the voltage between the selected word line (biased to VPGM) and the channel of the selected memory cells (biased to 0V) equals VPGM, which induces electric charge injection into the charge storage layer FG, and the selected cells are programmed. On the other hand, the bit line control circuit 2 imposes 2.5V, for example, on the unselected bit lines. In this case, the drain-side select transistors SD stay the OFF states. As a result, the channel of the memory cell MC uprises due to so-called self-boosting. And thereby the voltage between the selected word line and the channel of the unselected memory cell becomes small, and electric charge is not injected into the charge storage layer FG (lockout operation).

After the program operation described above, the verify-read operation is performed, in which the control circuit 5 selects the word line WL, and applies the verify-read voltage VCGRV to the selected word line (the step S11). The read-pass voltage VREAD is applied to the unselected word lines. VREAD does not depend on the threshold voltages of the memory cells MC. VREAD value can be uniformly equal or not among the unselected word lines.

After the control circuit 5 gives 0 V to the common source line CELSRC and applies a pre-charge voltage to the bit line BL, the select transistor SD and the select transistor SS are set to the “ON” state. When the threshold voltage of the memory cell MC is higher than the verify-read voltage VCGRV, the bit line charge is not discharged, and the bit line voltage does not change. This result is sensed and latched in the sense amplifier circuit, and thereby the data of the memory cell MC is judged as “0” data. On the other hand, when the threshold voltage of the memory cell MC is lower than the verify-read voltage VCGRV, the bit line charge is discharged, and the bit line voltage changes. This result is sensed and latched in the sense amplifier circuit, and thereby the data of the memory cell MC is judged as “1” data.

When 2-bit data are stored in one memory cell MC, the control circuit 5 changes the verify-read voltage sequentially as VCG_AV, VCG_BV, and VCG_CV, and thereby judges whether each of the selected memory cells MC is programmed up to its own target of the threshold voltage. Here, the memory cells that already reach their own threshold-voltage target are also referred to as “sufficiently programmed memory cells MS”. The memory cells that have not reached their own target are also referred to as “insufficiently programmed memory cells MS”.

In the verify-read operation, the control circuit 5 judges whether or not the number of the insufficiently programmed memory cells MC exceeds a given value. The given value may be zero, for example. Also the given value may be a positive value, considering the number of the insufficiently programmed memory cells MC relievable with ECC (Error Correction Codes). When the control circuit 5 judges that the number of the insufficiently programmed memory cells MC does not exceed the given value (verify-pass), the control circuit 5 finishes the program operation loops. On the other hand, when the control circuit 5 judges that the number of the insufficiently programmed memory cells MC exceeds the given value (verify-fail), the control circuit 5 goes on to the following step-up operation (the step S12).

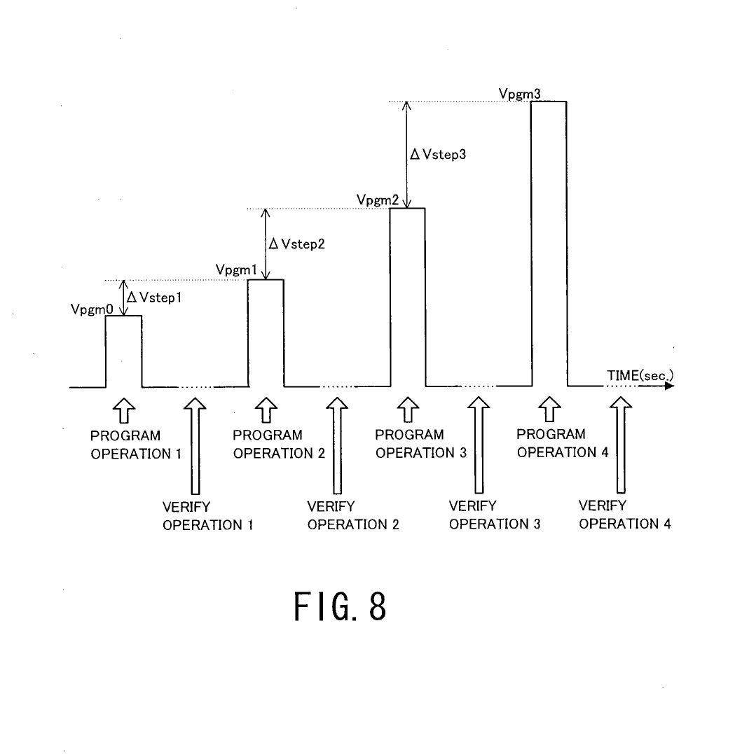

Setting of a step-up voltage in the step-up operation is described in the following part with reference to FIG. 8. FIG. 8 is a timing chart showing a voltage applied to a selected word line in the program operation of the NAND-type flash memory 100.

As shown in FIG. 8, when the control circuit 5 judges the selected word line to be incomplete, the step-up operation is performed. In the step-up operation, the step-up voltage ΔVstep is added to the program voltage used in the previous program operation, and the summation result is set as a new program voltage again (the step S12). The program voltage in the second program operation VPGM1 is expressed as (VPGM0+ΔVstep1), where VPGM0 is the program voltage of the first program operation loop, and ΔVstep1 is the step-up voltage of the first program operation loop. The program voltage of the third program operation, VPGM2, can also be expressed as (VPGM0+ΔVstep1+ΔVstep2), where ΔVstep2 is the step-up voltage of the second program operation loop.

In the step-up operation (the step S12) of the present invention, the step-up voltage ΔVstep is determined such that ΔVstep1<ΔVstep2<ΔVstep3< . . . <ΔVstep(n), where n is a natural number (n≧1). Each time the step-up operation is performed, the value of the step-up voltage ΔVstep becomes larger. Thus, the program voltage is increased in an accelerating manner.

Incremental values of the step-up voltage ΔVstep are stored in the ROM 7 provided in the NAND-type flash memory 100, for example. The control circuit 5 reads out the incremental values stored in the ROM 7. In addition, the incremental values of the step-up voltage ΔVstep may be sent from the memory controller HM (or an external host, etc.) along with the command.

When the control circuit 5 judges the selected word line to be incomplete, the control circuit 5 performs the program operation again using the updated program voltage determined by the step-up operation (the step S10). The operations from the step S10 to S12 are repeated until the number of the insufficient programmed cell becomes less than the given value. In addition, when the program operation loop count exceeds a prescribed number of times, and the number of the unsufficiently programmed cells still exceeds a target value, the control circuit 5 concludes that the programming is impossible, and finishes the program operation loop.

The read operation of the NAND-type flash memory 100 is described as follows: The control circuit 5 applies the read voltage VCGRV to the selected word line and the read-pass voltage VREAD to the all the other word lines (unselected word lines) in the same block. The values of VREAD of all the unselected word lines can be uniformly the same. Also these VREAD values may differ among the unselected word lines. Then, the control circuit 5 applies 0 V to the common source line CELSRC and the pre-charge voltage to the bit line BL. After these voltages are prepared, the control circuit 5 switches the select transistors SD and SS to the “ON” state. When the threshold voltage of the memory cell MC is higher than the read voltage, the electric charge in the bit line BL is not discharged. The voltage of the bit line BL is sensed by the sense amplifier circuit, and the data of the memory cell MC is judged as “0” data. On the other hand, when the threshold voltage of the memory cell MC is lower than the read voltage, the electric charge in the bit line BL is discharged. The voltage of the bit line BL is sensed by the sense amplifier circuit, and the data of the memory cell MC is judged as “1” data. In addition, 0 V (possibly, a positive voltage) is applied to the cell well 55 of the memory cell MC.

The read voltages VCGRV are set between the fragments of the threshold voltage distributions, as shown in FIG. 6. The read voltage VCG_AR is placed between “E” and “A” distributions. The read voltage VCG_BR is placed between “A” and “B” distributions. The read voltage VCG_CR is placed between “B” and “C” distributions.

The erase operation is performed block by block, for example. The control circuit 5 applies the voltage values shown in the “ERASE” row in FIG. 5 to the word lines and the bit lines. As a result, the voltage between the selected word line and the channel of the memory cell MC becomes large (with the opposite sign of the programming case), and the electric charge stored in the charge storage layer FG is extracted into the p-type well region. When the memory cell MS is not targeted to be erased, the corresponding word line WL is made unselected, and the unselected word lines are in the floating state. As a result, the unselected word lines uprise by the self-boost effect, and the voltage between the unselected word line and the channel of the memory cell MC becomes small. The electric charge stored in the charge storage layer FG of the unselected word line is not extracted into the p-type well region. Note that all the word lines in the same block is selected when the block is targeted to be erased, because the erase operation is performed block by block and performed to all the cells in the same block in the NAND-type flash memory. Therefore, the term “unselected word lines of the erase operation” refers to the word lines of unselected blocks. After the erase operation, the threshold voltages of all the memory cells MC in the block form the “E” distribution of FIG. 7.

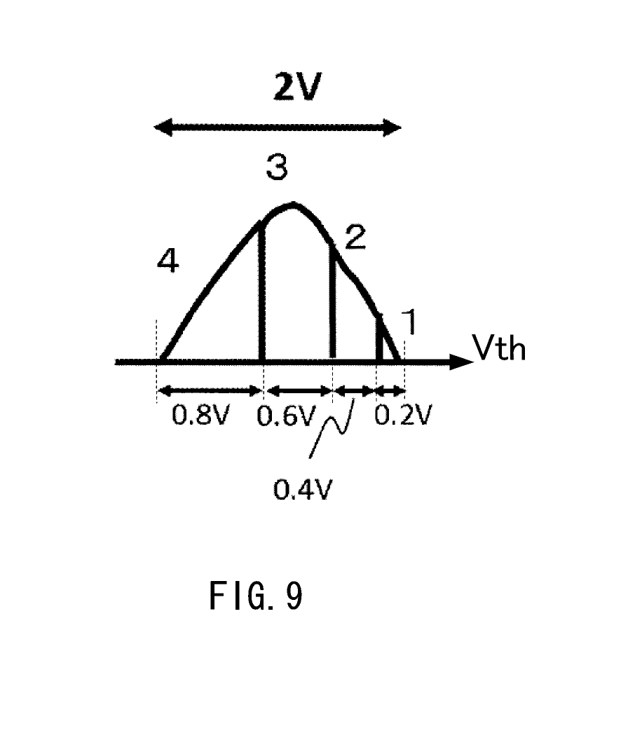

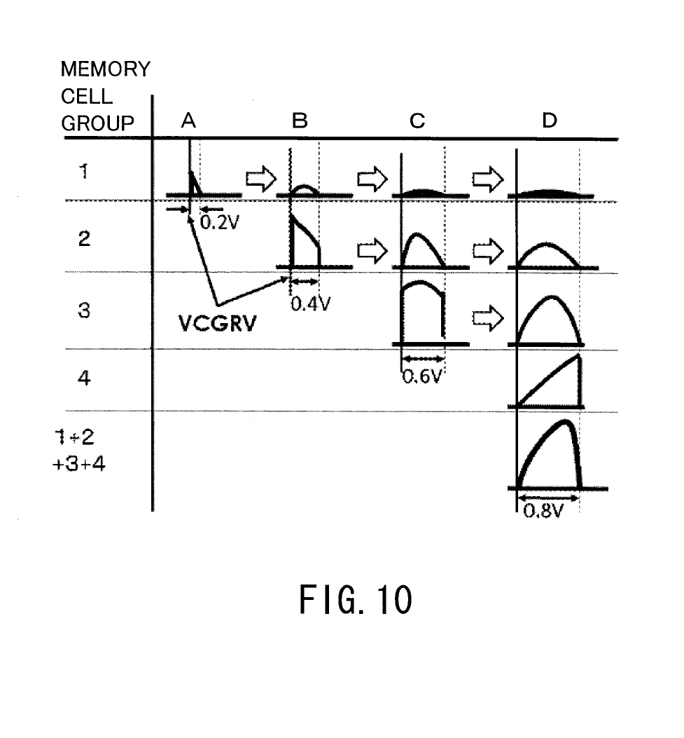

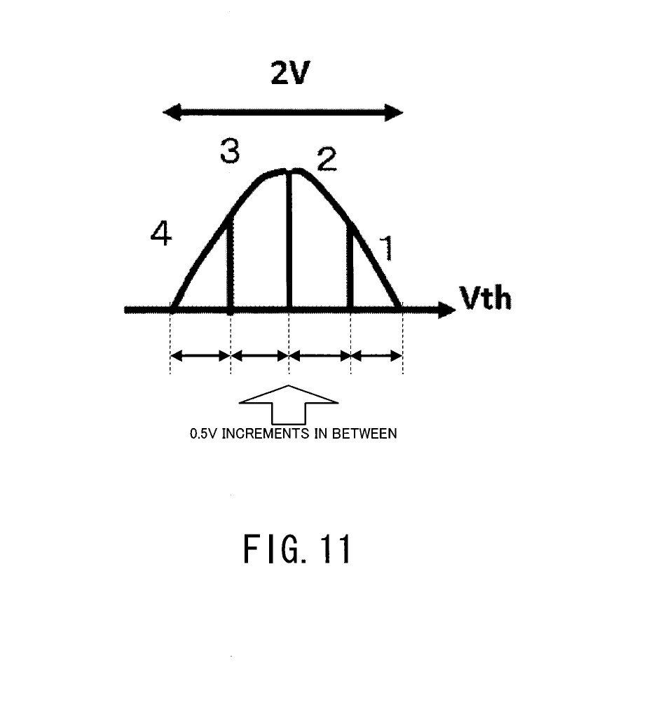

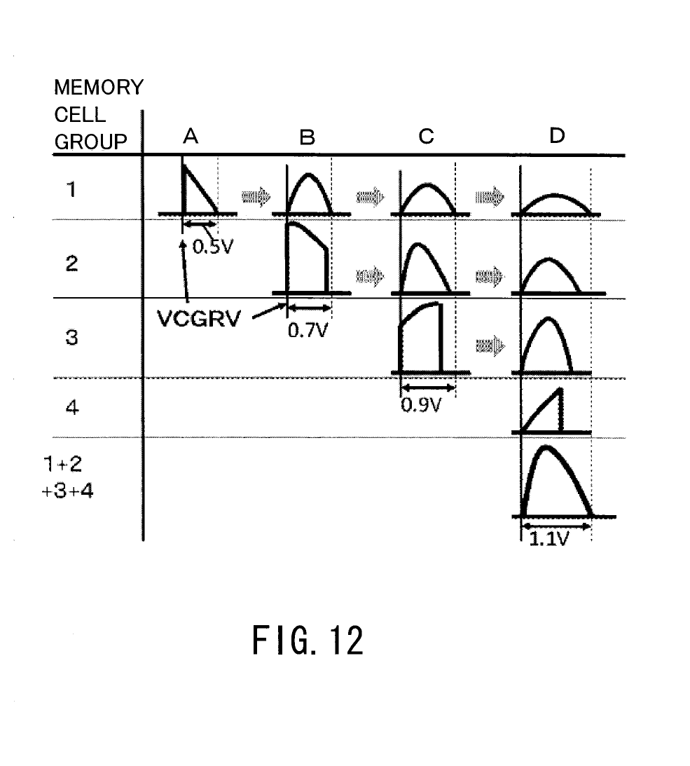

The effect of the present invention on the NAND-type flash memory 100 is described with reference to FIGS. 9 to 12 as follows: FIGS. 9 and 10 schematically show one example of evolution of the threshold voltage distribution in the program operation in the embodiment. FIGS. 11 and 12 schematically show one example of evolution of the threshold voltage distribution in the program operation in a comparative example.

As mentioned before, the program voltage VPGM is increased ΔVstep by ΔVstep every program loop. In the same way, the step-up voltage ΔVstep itself is also increased every program loop in the present invention. A new variable ΔΔVstep is here defined as a step-up value of ΔVstep, that is, ΔVstep increases ΔΔVstep by ΔΔVstep every program loop. In the embodiment (FIGS. 9 and 10), the incremental value ΔΔVstep is set to a constant value 0.2V. In this case, the step-up voltage ΔVstep is monotonically increased as 0.2V, 0.4V, 0.6V, 0.8V, and so on. On the other hand, in the comparative example (FIGS. 11 and 12), the incremental value ΔVstep is 0V, and the step-up voltage ΔVstep is constantly 0.5V. The later operation provides the program voltage VPGM rising at a constant speed.

FIGS. 9 and 11 are one example of schematic drawings of the “natural” threshold voltage distribution partitioned into four groups 1-4. The term “natural” means that the distribution is not generated by artificial manipulation like the program-verify operations. Ideally, all the cells have the same electric charge on them in the natural state. After the erase operation, the threshold voltage distribution is almost in the “natural” state. In both of FIGS. 9 and 11, the natural threshold voltage distributions are assumed to be 2V as shown in these figures. It is also assumed that the programming completes with five program loops of the program operation sequence. The programming speed of the embodiment (FIG. 9) and the comparative example (FIG. 11) is also assumed to be almost the same.

In both cases of the embodiment and the comparative example, each of the natural threshold voltage distributions is divided into four memory cell groups 1-4. The memory cells belonging to the same group pass the threshold voltage target (which is referred to as the “verify level” hereinafter) at the same program operation loop. The natural threshold voltage distribution shifts its position every program operation loop in the growing direction (from the left to the right in FIG. 9) without changing its shape. The magnitude of the voltage shift per one loop is approximately ΔVstep. The relative position of each cells in the natural threshold voltage distribution hardly changes. Therefore, the memory cell group 1 in FIG. 9 reaches the verify level first, the memory cell group 2 follows, the memory cell group 3 follows, and so on. The higher the natural threshold voltage is, the earlier the memory cell reaches the verify level and passes the verify-read operation. In the case of the embodiment (FIGS. 9 and 10), the upper tail (the righthand tail in FIG. 9) of the natural threshold voltage distribution reaches the verify level after the first program operation. After the second program operation, the natural threshold voltage distribution shifts its position as much as 0.2V in the righthand (higher) direction, and the memory cell group 1 reaches the verify level. The width of the memory cell group 1 is approximately 0.2V, because the step-up voltage ΔVstep is 0.2 V for the first step-up operation. For the same reason, the memory cell group 2 reaches the verify level after the third program operation. The width of memory cell group 2 is approximately 0.4V, because the step-up voltage ΔVstep is 0.4 V for the second step-up operation. In the same way, the memory cell groups 3 and 4 pass the verify level after the fourth and fifth program loops, respectively, and their threshold voltage width are about 0.6V and 0.8V, respectively. Note that the description above is about the “natural” threshold voltage distribution. When the program-verify operation is performed, the distribution shape below the verify level is equivalent to the natural threshold voltage distribution, while the distribution shape above the verify level changes, because the memory cells exceeding the verify level are inhibited to be programmed, and the shift of their threshold voltage is reduced.

In the case of the comparative example (FIGS. 11 and 12), the memory cell group 1 reaches the verify level after the second program operation (the program voltage is VPGM0+the step-up voltage of 0.5 V). The memory cell group 2 reaches the verify level after the third program operation (the program voltage is VPGM1+the step-up voltage of 0.5 V). Similarly, the memory cell groups 3 and 4 reach the verify level after the fourth and fifth program operations (the program voltages are VPGM2+the step-up voltage of 0.5 V and VPGM3+the step-up voltage of 0.5 V), respectively.

FIG. 10 shows the evolution of the threshold voltage distribution above the verify level under the program-verify operations in the embodiment. The threshold voltages of the memory cells belonging to the memory cell group 1 reach the verify voltage VCGRV (equal to the “verify level” defined above) after the second program operation (see the “A” column in FIG. 10). Then the memory cells belonging to the memory cell group 1 turn to the program inhibit state in the following program operation by the lockout operation.

After the third program operation, the threshold voltages of the memory cells belonging to the memory cell group 2 reach the verify voltage VCGRV (see the “B” column in FIG. 10). Then the memory cells belonging to the memory cell group 2 turn to the program inhibit state in the following program operation by the lockout operation. The memory cells belonging to the memory cell group 1 are in the program inhibit state during the third program operation. The memory cells of each group are randomly located on the selected word line. Therefore, some cells of the group 1 neighbor on a cell of the group 2, and others neighbor on a cell of the group 3 or 4.

Although the inhibited cells are not programmed during the program operation, their threshold voltages may shift upward due to cell-to-cell interference. The threshold voltages of the inhibited cells are affected by change of the electric charge of the adjacent cells. The magnitude of the threshold voltage shift due to cell-to-cell interference depends on the groups of the adjacent memory cells. For example, when both adjacent cells belong to the group 4, the voltage shifts of the inhibited cells are expected to be the greatest among all the combinations of the groups of adjacent cells, because the cells of the group 4 are programmed throughout all the program operations. On the other hand, if both adjacent cells belong to group 1, the threshold voltages of inhibited cells hardly change, because the programming of the adjacent cells is already finished at the second program operation, and the adjacent cells are in the program inhibit states after the second program operation, as well. The greater the shifts of the threshold voltages of the adjacent cells are, the greater the shifts of the threshold voltages of the inhibited cells are. Since the groups of the adjacent cells are randomly decided as described above, the magnitude of the threshold voltage shifts of the inhibited cells are also random. This randomness of the threshold voltage shifts of adjacent cells results in broadening of the threshold voltage distribution of inhibited cells.

Because of the broadening mechanism mentioned above, the threshold voltage distribution of the cells of the group 1 is broadened at the third program operation (see the “B” column of FIG. 10). The cells of the group 1 are in the program inhibit states at the third program operation. However, some of the adjacent cells are programmed at the third program operation, which results in the broadening of the threshold voltage distribution of the memory cell group 1.

Similarly, the threshold voltage distribution of the memory cell group 2 as well as the memory cell group 1 is broadened at the fourth program operation. The memory cell groups 1 and 2 are in the program inhibit states at the fourth program operation. The threshold voltage distribution of the memory cell group 3 is also broadened at the fifth program operation, as well as the memory cell groups 1 and 2.

The width of the threshold voltage of each cell group is broadened as much as 0.2V per one program operation in this example. All the cell groups have the threshold voltage distribution of 0.8V width. Therefore, the threshold voltage distribution of the whole word line has 0.8V width after the fifth (and last) program operation, as shown in the lowest column in FIG. 10.

Evolution of the threshold voltage distribution in the comparative example is shown in FIG. 12. Since the contents of the operations are the same as the embodiment, the description thereof is omitted here. The result of the program operations in the comparative example is shown in the lowest column in FIG. 12. The width of the threshold voltage distribution of the whole word line is as much as 1.1 V after the last program operation.

The width of the threshold voltage distribution of the memory cell group 1 is the most broadened after the cell group 1 reaches the verify-read voltage VCGRV, as shown in FIG. 10. Since the upper-tail threshold voltage of the memory cell group 1 is initially low, however, the final upper-tail threshold voltage of the cell group 1 still stays low and is approximately the same as that of the cell group 4 (see FIG. 10). The cell groups 2 and 3 also have almost the same upper-tail position at the end of the programming. Therefore, the upper-tail threshold voltage of the whole word line is approximately the same as that of all the cell groups, which is relatively low.

On the other hand, in the comparative example (FIG. 12), since the step-up width of the program voltage is constant, the threshold voltage distribution of the cell group 1 is relatively broad from the beginning of the program operation sequence. Then the upper-tail threshold voltage of the cell group 1 is larger than that of the cell group 4 at the end of program operation sequence, and consequently the threshold voltages of the whole word line are more distributed than the embodiment.

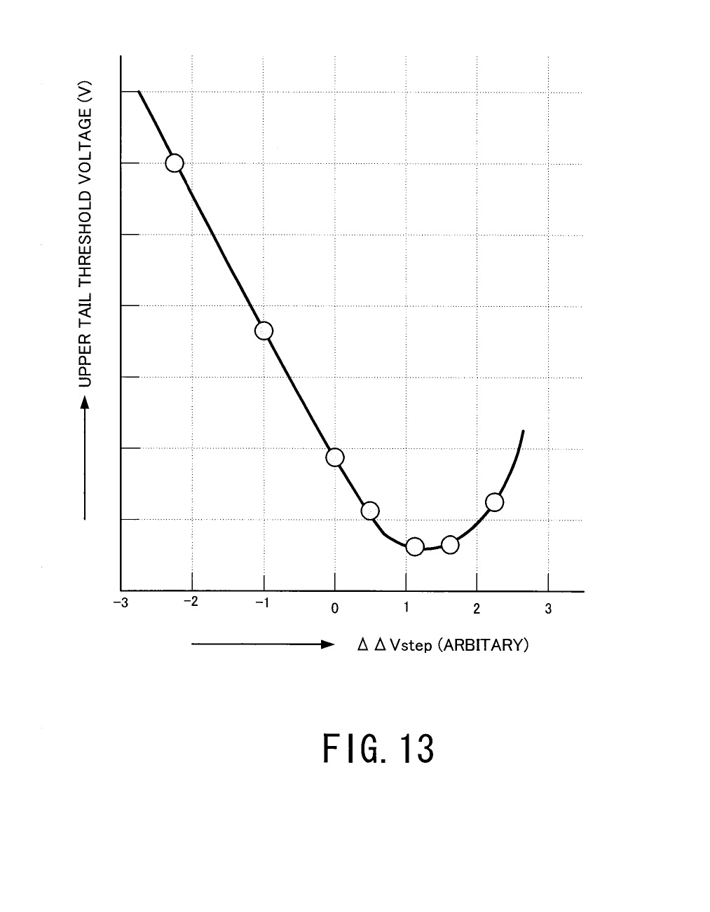

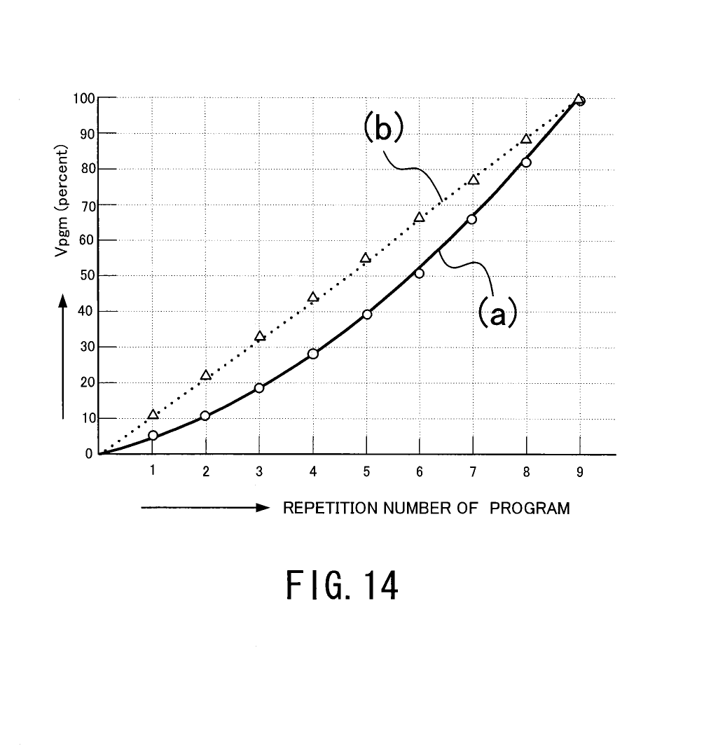

To show the above effect more clearly, Monte Carlo simulations are conducted (see FIGS. 13 and FIG. 14). FIG. 13 is simulation results showing the relation between the upper-tail threshold voltage of the whole word line and the incremental value ΔΔVstep of the step-up voltage ΔVstep. The upper-tail threshold voltage is desired to be low. In these simulations, the loop count of the program operations is kept constant (i.e. an initial ΔVstep value is chosen to satisfy such a condition). Therefore, all the programming methods on FIG. 13 require the same programming time. As it can be seen from FIG. 13, there exist finite ΔΔVstep values reducing the upper-tail threshold voltage compared to the ΔΔVstep=0 case. Therefore, the present invention has a desirable effect on the threshold voltage distribution. Also it can be seen from FIG. 13 that there exists the minimum point between ΔΔVstep=1 and ΔΔVstep=2 (in arbitrary units). The incremental value ΔΔVstep has a proper value (critical value).

FIG. 14 shows the relation between the program operation count and the program voltages used in the simulations shown in FIG. 13. In FIG. 14, a solid line (a) shows the embodiment, and a dashed line (b) shows the comparative example.

As shown in FIG. 13, a proper ΔΔVstep value exists in the embodiment. A too large ΔΔVstep value results in increase of the program voltage steps in the last half of the program operations, and the upper-tail threshold voltage becomes high. The upper tail of the threshold voltage distribution of the memory cell group 4 shown in FIG. 9 becomes high, for example. On the other hand, if a too small ΔΔVstep is chosen, a large initial ΔVstep value (ΔVstep1 in FIG. 8) is required to avoid increase of the total program operation count (The increase of the program operation count results in undesirable degradation of programming speed). Then the program voltage steps in the first half of the program operations become large. In other words, the widths of the threshold voltage distributions of the memory cell group 1 and the memory cell group 2 shown in FIG. 9, become large, respectively, for example.

As described above, it is found that the incremental values ΔΔVstep has a proper value to reduce the width of the threshold voltage distribution without loss of the programming speed. Adjusting the incremental value ΔΔVstep to the proper value, the threshold voltage distribution can be reduced without loss of the programming speed. Accordingly, it is possible to improve the reliability of the data of NAND-type non-volatile semiconductor storage device.

In addition, the incremental value ΔΔVstep of the step-up voltage ΔVstep can be a constant value. It is possible to reduce the threshold voltage distribution without complicated control of program operations or loss of the programming speed.

A physical interval between NAND-type flash memory cells has been becoming narrower and narrower due to increase of storage capacity and cell number density. This shrinkage of cell size brings greater cell-to-cell interference. Even when the cell size of the NAND-type flash memory is reduced, it is possible to improve the reliability of the data of the NAND-type flash memory by applying the program operation according to the embodiment.

In addition, a proper value for the incremental value ΔΔVstep can be obtained with a simulation etc. and can be stored in a ROM before a shipment of the product. In addition, a proper value for the incremental value ΔΔVstep is calculated at the time of a die sort test, and can be stored in the ROM 7 before the shipment of the product.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A NAND-type non-volatile semiconductor storage device, comprising:
a memory cell array having a memory string in which more than one of memory cells are connected in series, a word line connected to more than one of memory cells, and a bit line connected to one end of the memory string; and
a control circuit being configured to perform a program operation, a verify operation, and a step-up operation in a program operation loop, the control circuit being configured to perform the program operation to apply a program voltage to the word line, the control circuit being configured to perform the verify operation after the program operation, the control circuit being configured to perform the step-up operation to program a memory cell judged to be insufficiently programmed at the verify-read operation using a step-up voltage,
wherein the control circuit is configured to set the step-up voltage increasing, each time the step-up operation is performed.

2. The device according to claim 1, wherein the control circuit, in the verify-read operation, is configured to control a voltage of the bit line connected to a memory cell judged to be sufficiently written in write to be inhibit state.

3. The device according to claim 1, wherein the control circuit is configured to finish the program operation when the number of memory cells judged to be insufficiently programmed becomes not more than a target value, and to monotonously increase a value of the step-up voltage until the program operation is finished.

4. The device according to claim 1, wherein a step-up value of the step-up voltage is calculated based on the balance between an increase in the program voltage at a last half of the program operation and an effect of interference between the memory cells at a first half of the program operation.

5. The device according to claim 1, wherein a step-up value of the step-up voltage is set to a constant value.

6. The device according to claim 1, wherein when the memory cell has threshold voltages of n bits (provided that n is an integer of not less than 1), the 2ⁿth threshold voltage is verify-passed in at least the (2ⁿ+1)th program operation.

7. The device according to claim 1, further comprising a ROM.

8. The device according to claim 7, wherein a step-up value of the step-up voltage is calculated at a D/S test, and an adjusted value of the step-up value is stored in the ROM.

9. The device according to claim 8, wherein the value stored in the ROM is used as the step-up value of the step-up voltage.

10. The device according to claim 7, wherein step-up value of the step-up voltage is calculated by using a simulation, and an adjusted value of the step-up value is stored in the ROM.

11. The device according to claim 10, wherein the value stored in the ROM is used as the step-up value of the step-up voltage.

12. The device according to claim 1, wherein a first selection transistor, a second selection transistor, a first dummy memory cell, and a second dummy memory cell are disposed in the memory cell string, and wherein:
the first dummy memory cell is provided between the first select transistor and the memory string; and
the second dummy memory cell is provided between the memory string and the second select transistor.
